(19) United States
(12) Patent Application Publication
(10) Pub. No.: US 2024/0396546 A1
(43) Pub. Date: Nov. 28, 2024

(54) METHODS AND SYSTEMS OF OPERATING A DOUBLE-SIDED DOUBLE-BASE BIPOLAR JUNCTION TRANSISTOR

(71) Applicant: IDEAL POWER INC., Austin, TX (US)

(72) Inventors: Mudit KHANNA, Austin, TX (US); Jiankang BU, Austin, TX (US); Ruiyang YU, Austin, TX (US); Yifan JIANG, Austin, TX (US); R. Daniel BRDAR, Driftwood, TX (US)

(73) Assignee: IDEAL POWER INC., Austin, TX (US)

(21) Appl. No.: 18/422,469

(22) Filed: Jan. 25, 2024

Related U.S. Application Data
(60) Provisional application No. 63/504,464, filed on May 26, 2023.

(51) Int. Cl. H03K 17/60; H03K 17/567; H01L 29/10; H01L 29/732

(52) U.S. Cl. CPC H03K 17/60; H03K 17/567; H01L 29/1004; H01L 29/732

(57) ABSTRACT

Double-sided double-base bipolar junction transistor, and methods of operation. One example is a method comprising conducting main load current from an upper terminal of a switch assembly, through a double-sided double-base bipolar junction transistor (DSDB-BJT) of the switch assembly, and then through a lower terminal of the switch assembly. The conducting may be by: injecting charge carriers into an upper drift region of the DSDB-BJT as the main load current flows into an upper collector-emitter of the DSDB-BJT; and simultaneously injecting charge carriers into a lower drift region of the DSDB-BJT as main load current flows out of a lower collector-emitter of the DSDB-BJT.

### CROSS-REFERENCE TO RELATED APPLICATIONS

This application claims the benefit of U.S. Provisional App. No. 63/504,464 filed May 26, 2023 titled “Methods and Systems of Operating a Double-Sided Double-Base Bipolar Junction Transistor.” The provisional application is incorporated by reference herein as if reproduced in full below.

### BACKGROUND

A double-sided double-base (DSDB) bipolar junction transistor (BJT) is junction transistor constructed with a base and collector-emitter on a first side of the bulk region, and a distinct and separate base and collector-emitter on a second side of the bulk region, opposite the first side. When properly configured by an external driver, electrical current may selectively flow through the collector-emitters of the DSDB-BJT in either direction, and thus such devices are considered bi-directional devices.

### SUMMARY

At least one example is a method comprising: conducting main load current from an upper terminal of a switch assembly, through a double-sided double-base bipolar junction transistor (DSDB-BJT) of the switch assembly, and then through a lower terminal of the switch assembly. The conducting may be by: injecting charge carriers into an upper drift region of the DSDB-BJT as the main load current flows into an upper collector-emitter of the DSDB-BJT; and simultaneously injecting charge carriers into a lower drift region of the DSDB-BJT as main load current flows out of a lower collector-emitter of the DSDB-BJT.

In the example method: injecting charge carriers into the upper drift region of the DSDB-BJT may comprise injecting an upper control current into an upper base of the DSDB-BJT; and injecting charge carriers into the lower drift region of the DSDB-BJT may comprise injecting a lower control current into a lower base of the DSDB-BJT. A magnitude of the upper control current may be the same as a magnitude of the lower control current. The magnitude of an upper bias voltage between the upper base and upper collector-emitter may be different a magnitude of a lower bias voltage between the lower base and the lower collector-emitter. The magnitude of the upper control current may be different than a magnitude of the lower control current.

Conducting the main load current may comprise conducting the main load current through the DSDB-BJT that is a monolithic structure with a continuous drift region. Conducting main load current may comprise conducting main load current through the upper collector-emitter, then through the upper drift region, then though a metallic material that bonds to the upper drift region to the lower drift region, and then through the lower collector-emitter.

In the example method: injecting charge carriers into the upper drift region of the DSDB-BJT may comprise injecting an upper control current through a metallic material that bonds the upper drift region to the lower drift region; and injecting charge carriers into the lower drift region of the DSDB-BJT may comprise injecting a lower control current through the metallic material.

Another example is a switch assembly comprising: an upper terminal, a lower terminal, and a control input; a double-sided double-base bipolar junction transistor (DSDB-BJT) defining an upper base, an upper collector-emitter, a lower base, and a lower collector-emitter; an upper-main FET defining a first lead coupled to the upper terminal, a second lead coupled to the upper collector-emitter, and a gate; a lower-main FET defining a first lead coupled to the lower collector-emitter, a second lead coupled to the lower terminal, and a gate; and a driver coupled to the control input, the gate of the upper-main FET, the gate of the lower-main FET, and the upper and lower bases of the DSDB-BJT. Responsive to assertion of the control input, and for a first applied voltage across the upper terminal and lower terminal, the driver may be configured to: arrange the DSDB-BJT for conduction; inject charge carriers into an upper drift region of the DSDB-BJT and simultaneously inject charge carriers into a lower drift region of the DSDB-BJT; and assert the gate of the lower-main FET to make the lower-main FET conductive such that a first load current flows from the upper terminal to the lower terminal.

In the example switch assembly, the DSDB-BJT may comprise the upper drift region associated with the upper collector-emitter and the lower drift region associated with the lower collector-emitter, and wherein the upper drift region is bonded to the lower drift region. When driver injects charge carriers into the upper drift region, the driver may be configured to inject an upper current into the upper base; and when driver injects charge carriers into the lower drift region, the driver may be configured to inject a lower current into the lower base. When the driver injects charge carriers into the upper drift region, the driver may be configured to inject an upper control current through a metallic layer that bonds the upper drift region to the lower drift region; and when the driver injects charge carriers into the lower drift region, the driver may be configured to inject a lower control current through the metallic layer.

In the example switch assembly, the DSDB-BJT may comprise a monolithic structure with a continuous drift region. When driver injects charge carriers into the upper drift region, the driver may be configured to inject an upper current into the upper base; and when driver injects charge carriers into the lower drift region, the driver may be configured to inject a lower current into the lower base.

In the example switch assembly, responsive to de-assertion of the control input, the driver may be configured to: de-assert the gate of the upper-main FET to make the upper-main FET non-conductive; de-assert the gate of the lower-main FET to make the lower-main FET non-conductive such that no current flows from the lower collector-emitter to the lower terminal; and arrange the DSDB-BJT into a non-conductive state by coupling the upper base to the upper collector-emitter and coupling the lower base to the lower terminal.

In the example switch assembly, responsive to assertion of the control input, and for a first applied voltage across the upper terminal and the lower terminal, the driver may be further configured to assert the gate of the upper-main FET to make the upper-main FET conductive.

### BRIEF DESCRIPTION OF THE DRAWINGS

For a detailed description of example embodiments, reference will now be made to the accompanying drawings in which:

FIG. 1 shows a switch assembly in accordance with at least some embodiments;

FIG. 2 shows a bidirectional switch in accordance with at least some embodiments;

FIGS. 3A-3F show a double-sided double-base bipolar junction transistor of PNP construction in shorthand form, with example external electrical connections, to illustrate several operational states;

FIGS. 4A-4G show a modular double-sided double-base bipolar junction transistor of PNP construction in shorthand form, with example external electrical connections, to illustrate several operational states;

FIGS. 5A-5F show a modular double-sided double-base bipolar junction transistor of PNP construction in shorthand form, with example external electrical connections, to illustrate several operational states;

FIG. 6 shows a block diagram of a driver in accordance with at least some embodiments; and

FIG. 7 shows method in accordance with at least some embodiments.

### DEFINITIONS

Various terms are used to refer to particular system components. Different companies may refer to a component by different names-this document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or a direct connection. Thus, if a first device couples to a second device, that connection may be through a direct connection or through an indirect connection via other devices and connections.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate that the recited referent may be plural.

“About” in reference to a recited parameter shall mean the recited parameter plus or minus ten percent (+/−10%) of the recited parameter.

“Assert” shall mean creating or maintaining a first predetermined state of a Boolean signal. Boolean signals may be asserted high or with a higher voltage, and Boolean signals may be asserted low or with a lower voltage, at the discretion of the circuit designer. Similarly, “de-assert” shall mean creating or maintaining a second predetermined state of the Boolean, opposite the asserted state.

“FET” shall mean a field effect transistor, such as a junction-gate FET (JFET) or metal-oxide-silicon FET (MOSFET).

“Closing” in reference to an electrically-controlled switch (e.g., a FET) shall mean making the electrically-controlled switch conductive. For example, closing a FET used as an electrically-controlled switch may mean driving the FET to the fully conductive state.

“Opening” in reference to an electrically-controlled switch (e.g., a FET) shall mean making the electrically-controlled switch non-conductive. Leakage current shall not negate the status of an electrically-controlled switch being non-conductive.

“DSDB-BJT” shall mean a double-sided double-base (DSDB) bipolar junction transistor (BJT) having base and collector-emitter on a first side of a drift region, and a distinct and separate base and collector-emitter on a second side of the drift region, opposite the first side. The drift region may be continuous, or the drift region may comprise an upper drift region associated with the upper base and upper collector-emitter, and a lower drift region associated with the lower base and lower collector-emitter.

“Collector-emitter” of a bipolar junction transistor shall mean a region of the bipolar junction transistor through which main load current flows. For purposes of this specification and claims, the designation as a collector-emitter is independent of the underlying device physics within the bipolar junction transistor. For example, for a double-sided double-base PNP transistor, the main load current may flow from an upper P-type region, through the bulk N-type drift region, and then out the lower P-type region, and when so used the upper P-type region and the lower P-type region are considered collector-emitters. However, in other cases, such as described in co-pending and commonly assigned U.S. application Ser. No. 18/483,939 filed Oct. 10, 2023 and titled “Methods and Systems of Operating a PNP Bi-Directional Double-Base Bipolar Junction Transistor,” the main load current may flow from an upper N-type region, through the bulk N-type drift region, and then through the lower N-type region, and when so used the upper and lower N-type regions are considered collector-emitters.

“Base” of a bipolar junction transistor shall mean a region of the bipolar junction transistor through which control current flows, the control current distinct from the main load current. For purposes of this specification and claims, the designation as a base is independent of the underlying device physics within the bipolar junction transistor. For example, for a double-sided double-base PNP transistor, the control current may flow into an upper N-type region or a lower N-type region, and when so used the upper N-type region and the lower N-type region are considered bases. However, in other cases, such as described in co-pending and commonly assigned U.S. application Ser. No. 18/483,939 noted above, the control current may flow into an upper P-type region or a lower P-type region, and when so used the upper and lower P-type regions are considered bases.

“Upper” in reference to component (e.g., upper collector-emitter, upper base) shall not be read to imply a location of the recited component with respect to gravity. Upper may be derived from location of the device in an example drawing.

“Lower” in reference to a component (e.g., upper collector-emitter, upper base) shall not be read to imply a location of the recited component with respect to gravity. Lower may be derived from location of the device in an example drawing.

The terms “input” and “output” when used as nouns refer to connections (e.g., electrical, software), and shall not be read as verbs requiring action. For example, a timer circuit may define a clock output. The example timer circuit may create or drive a clock signal on the clock output. In systems implemented directly in hardware (e.g., on a semiconductor substrate), these “inputs” and “outputs” define electrical connections. In systems implemented in software, these “inputs” and “outputs” define parameters read by or written by, respectively, the instructions implementing the function.

“Controller” shall mean, alone or in combination, individual circuit components, an application specific integrated circuit (ASIC), a microcontroller with controlling software, a reduced-instruction-set computing (RISC) with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Various examples are directed to methods and systems of operating a double-sided double-base bipolar junction transistor (DSDB-BJT). More particularly, various examples are directed to driving DSDB-BJTs to reduce forward voltage drop. More particularly still, various examples are directed operating techniques to reduce forward voltage drop for DSDB-BJTs, particular DSDB-BJTs created by bonding the drift region of an upper component (with its upper base and upper collector-emitter) to the drift region of a lower component (with its lower base and lower collector-emitter).

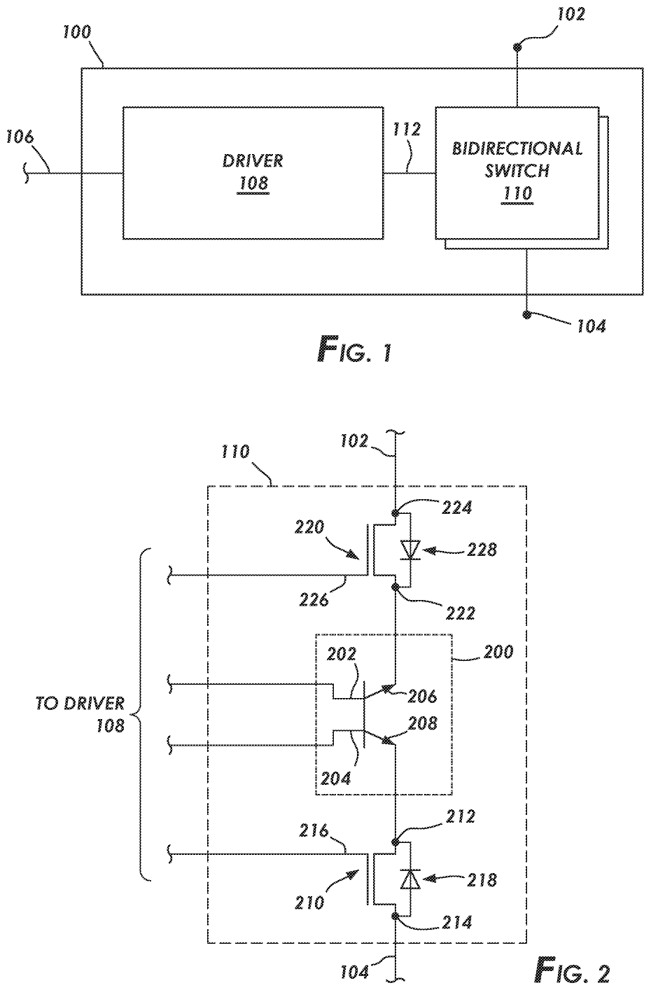

FIG. 1 shows an example switch assembly 100. In particular, the example switch assembly 100 defines an upper terminal 102, a lower terminal 104, and a control input or control terminal 106. Internally, the example switch assembly 100 includes a driver 108 and a bidirectional switch 110. The driver 108 defines the control terminal 106, and the driver 108 is coupled to the bidirectional switch 110, as shown by connections 112. As discussed in greater detail below, the connections 112, though shown as a single connection, represents a plurality of electrical connections to the bidirectional switch 110. The driver 108 controls the conductive state of the bidirectional switch 110 by arranging the voltages/currents on the connections 112.

One example of the switch assembly 100 may include a single bidirectional switch 110. Another example switch assembly 100 may have two or more bidirectional switches 110, as illustrated in FIG. 1 by the “stacked” arrangement for the bidirectional switch 110. When multiple bidirectional switches 110 are present, the bidirectional switches 110 are electrically connected in parallel to share the main load current (forward or reverse). So as not to unduly complicate the specification, the discussion that follows assumes a single bidirectional switch 110. However, one having ordinary skill, and with the benefit of this disclosure, understands that the multiple bidirectional switches may be present depending on the designed current carrying capability of any specific switch assembly 100.

FIG. 2 shows a schematic of an example bidirectional switch 110. In particular, the example bidirectional switch 110 comprises a DSDB-BJT 200. The example DSDB-BJT 200 defines an upper base 202, a lower base 204, an upper collector-emitter 206, and a lower collector-emitter 208. The example bidirectional switch 110 further includes lower-main or lower cascode FET 210 that defines a drain 212 coupled to the lower collector-emitter 208, a source 214 coupled to the lower terminal 104, a gate 216 coupled to the driver 108, and a body diode 218. Finally, the example bidirectional switch 110 includes an upper-main or upper cascode FET 220 that defines a drain 222 coupled to the upper collector-emitter 206, a source 224 coupled to the upper terminal 102, a gate 226 coupled to the driver 108, and a body diode 228.

The driver 108 is coupled to the bidirectional switch 110 by a plurality of electrical connections. In the example of FIG. 2, the electrical connections to the driver 108 may comprise connections to: the gate 226 of the upper cascode FET 220; the upper base 202; the lower base 204; and the gate 216 of the lower cascode FET 210. In order to describe when each of these connections to the driver 108 may be active, the specification turns to example operation of a DSDB-BJT 200.

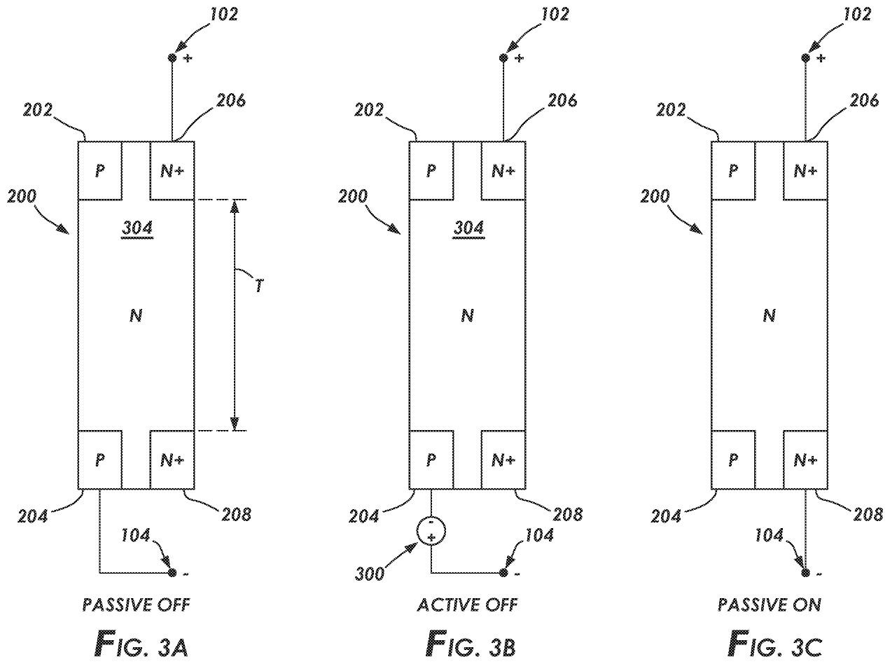

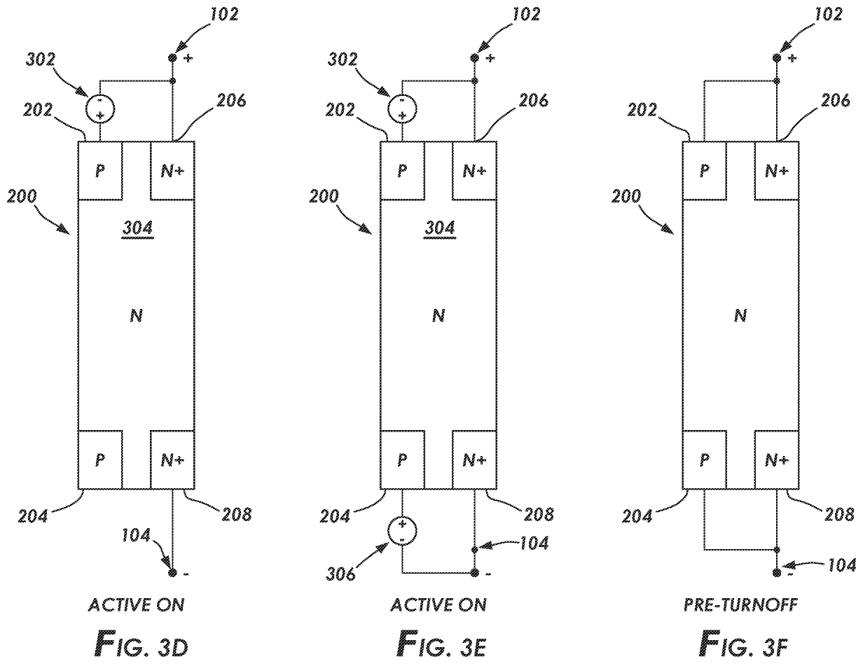

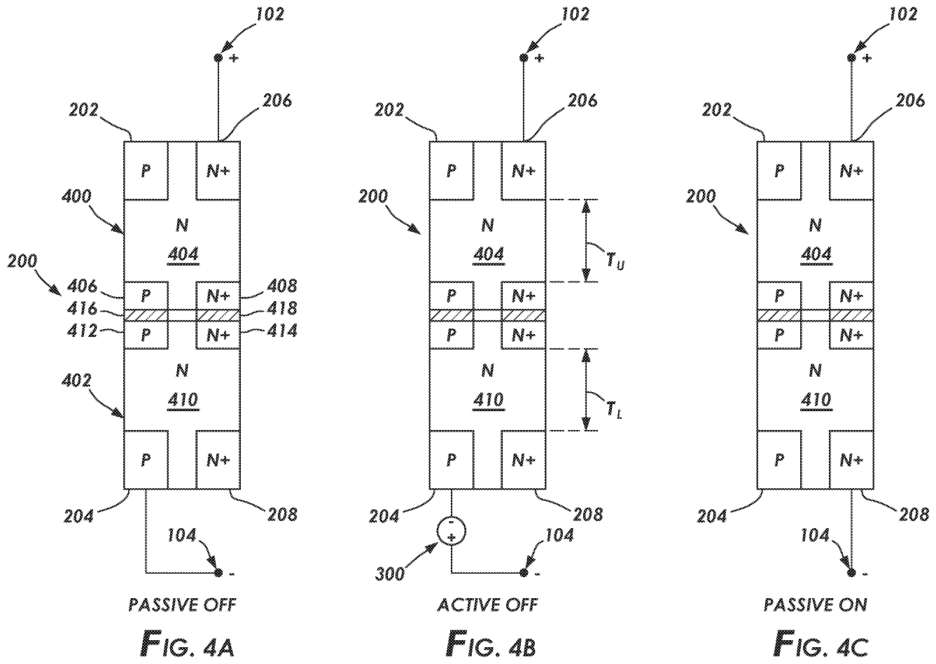

FIGS. 3A-3F show, in shorthand form, a partial cross-sectional view of an example DSDB-BJT 200 of PNP construction to illustrate several operational states. In particular, FIGS. 3A-3F show six example states of the DSDB-BJT 200 arranged for the main load current to be carried across or through the N-type regions, the six states being: passive off (FIG. 3A); active off (FIG. 3B); passive on (FIG. 3C); active on (FIG. 3D); an alternative active on (FIG. 3E); and pre-turn off (FIG. 3F). In the examples of FIGS. 3A-3F, the switch assembly 100 is assumed to be forward biased (e.g., having the more positive polarity associated with the upper terminal 102 relative to the lower terminal 104).

FIG. 3A shows a passive-off arrangement of the example DSDB-BJT 200. FIG. 3A shows the upper terminal 102 and lower terminal 104. Electrically between the upper terminal 102 and the lower terminal 104 resides the DSDB-BJT 200. The upper base 202 is electrically floated by the driver 108. The upper collector-emitter 206 is coupled to the upper terminal 102, such as through the upper cascode FET 220 or its body diode 228. The lower base 204 is coupled to the lower terminal 104 by the driver 108. The lower collector-emitter 208 is electrically floated, such as by the lower cascode FET 210 being open and its body diode 218 being non-conductive because of the applied voltage. In the arrangement of FIG. 3A, no appreciable current flows through the DSDB-BJT 200 because of the blocking performed by the PN junction formed between the lower base 204 and the drift region 304. The state of FIG. 3A is referred as “passive off” because the electrical arrangement can be implemented with purely passive components (e.g., diodes and resistors), and thus the driver 108 need not have operational power to implement the arrangement of FIG. 3A. In the passive-off arrangement, the DSDB-BJT 200 blocks voltage and current, and thus the non-conductive lower cascode FET 210 may experience a relatively small drain-to-source voltage (e.g., 30V or less for 1200V applied across the upper terminal 102 and lower terminal 104).

FIG. 3B shows an active-off arrangement of the example DSDB-BJT 200. In particular, the upper base 202 is electrically floated by the driver 108. The upper collector-emitter 206 is coupled to the upper terminal 102, such as through the upper cascode FET 220 or its body diode 228. The lower base 204 is coupled, through the driver 108, to the lower terminal 104 by way of a voltage source 300. The lower collector-emitter 208 is electrically floated, such as by the lower cascode FET 210 being open and its body diode 218 being non-conductive because of the applied voltage. The voltage source 300 provides a negative bias to the lower base 204 relative to the lower collector-emitter 208. In the active-off arrangement, no appreciable current flows through the DSDB-BJT 200 because of the blocking performed by the PN junction formed between the lower base 204 and the drift region 304. The example state of FIG. 3B is referred as “active off” because in the electrical arrangement of FIG. 3B the driver 108 uses operational power to implement the arrangement (e.g., to power the voltage source 300). In the active-off arrangement of FIG. 3B, again the DSDB-BJT 200 blocks voltage and current, and thus the non-conductive lower cascode FET 210 may experience a small drain-to-source voltage (e.g., 30V or less).

FIG. 3C shows a passive-on arrangement of the example DSDB-BJT 200. In particular, the upper base 202 is electrically floated by the driver 108. The upper collector-emitter 206 is coupled to the upper terminal 102, such as through the upper cascode FET 220 or its body diode 228. The lower base 204 is electrically floated by the driver 108. The lower collector-emitter 208 is coupled to the lower terminal 104 by way of the lower cascode FET 210. The voltage drop across the DSDB-BJT 200 in the arrangement of FIG. 3C is based on the substrate resistance (e.g., for a 160 micron thick substrate, about 2 ohms). For an example 30 Amps (A) of main load current, in the passive-on arrangement the DSDB-BJT 200 has a voltage drop of about 60V measured from the upper collector-emitter 206 to the lower collector-emitter 208. The example state of FIG. 3C is referred as “passive on” because the conductive state does not involve injection of charge carriers to lower the forward voltage drop V_{CEON}. An example of injection of charge carriers is shown in the active-on arrangement of FIG. 3D.

FIG. 3D shows an active-on arrangement of the example DSDB-BJT 200, still with the switch assembly 100 forward biased. In particular, the upper base 202 is coupled, through the driver 108, to the upper terminal 102 by way of a voltage source 302. The upper collector-emitter 206 is coupled to the upper terminal 102, such as through the upper cascode FET 220 or its body diode 228. The lower base 204 is electrically floated by the driver 108. The lower collector-emitter 208 is coupled to the lower terminal 104 through lower cascode FET 210. The voltage source 302 provides a positive bias to the upper base 202 relative to the upper collector-emitter 206, and the voltage source 302 may provide any suitable bias voltage (e.g., 0.2 V to 2V). The voltage source 302 injects charge carriers across the PN junction into the bulk substrate or drift region 304, which lowers forward voltage drop V_{CEON}, measured from the upper collector-emitter 206 to the lower collector-emitter 208, to about 0.2V for 30A of main load current.

FIG. 3E shows an alternative active-on arrangement of the example DSDB-BJT 200, still with the switch assembly 100 forward biased. In particular, the upper base 202 is coupled, through the driver 108, to the upper terminal 102 by way of the voltage source 302. The upper collector-emitter 206 is coupled to the upper terminal 102, such as through the upper cascode FET 220 or its body diode 228. The lower base 204 is coupled, through the driver 108, to the lower terminal 104 by way of a voltage source 306. The lower collector-emitter 208 is coupled to the lower terminal 104 through lower cascode FET 210. The voltage source 302 provides a positive bias to the upper base 202 relative to the upper collector-emitter 206, and the voltage source 306 provides a positive bias to the lower base 204 relative to the lower collector-emitter 208. The voltage source 302 injects charge carriers across the upper PN junction into the drift region 304, and the voltage source 306 injects charge carriers across the lower PN junction in the drift region 304. The injection of charge carriers lowers forward voltage drop V_{CEON}, measured from the upper collector-emitter 206 to the lower collector-emitter 208, again to about 0.2V for 30A of main load current.

FIG. 3F shows a pre-turnoff arrangement of the example DSDB-BJT 200. In particular, the upper base 202 is coupled, by way of the driver 108, to the upper terminal 102. The upper collector-emitter 206 is coupled to the upper terminal 102, such as through the upper cascode FET 220 or its body diode 228. The lower base 204 is coupled, by the driver 108, to the lower terminal 104. The lower collector-emitter 208 is coupled to the lower terminal 104 by way of the lower cascode FET 210. An equivalent arrangement may be to omit the coupling of the upper base 202 to the upper terminal 102. In the pre-turnoff arrangement of FIG. 3F, the example DSDB-BJT 200 presents about a 2-Ohm resistance across the terminals 102 and 104. Thus, for the example 30A main load current, in the pre-turn off arrangement of FIG. 3F the DSDB-BJT 200 presents about a 60V drop measured from the upper collector-emitter 206 to the lower collector-emitter 208.

With respect to transitions of the switch assembly 100 from non-conductive to conductive, the example DSDB-BJT 200 may be arranged to transition from either the passive-off arrangement of FIG. 3A or active-off arrangement of FIG. 3B directly to one of the active-on arrangements of FIG. 3D or 3E without implementing an intermediate arrangement or state. Nevertheless, the passive-on arrangement of FIG. 3C may find use in some circumstances. With the respect to transitions of the switch assembly 100 from conductive to non-conductive, the example DSDB-BJT 200 may be transitioned from one of the active-on arrangements of FIG. 3D or 3E directly to the active-off arrangement of FIG. 3B or the passive-off arrangement of FIG. 3A without implementing an intermediate arrangement or state. Nevertheless, the passive-on arrangement of FIG. 3C and the pre-turnoff arrangement of FIG. 3F may find use in some circumstances.

The examples of FIGS. 3A-3F are for the switch assembly 100 being forward biased. However, the example DSDB-BJT 200 is a symmetrical device, and now understanding how to control l current through the DSDB-BJT when the switch assembly 100 is forward biased, control of current when the switch assembly 100 is reverse biased (i.e., having the more positive polarity associated with the lower terminal 104 relative to the upper terminal 102) directly follows. Moreover, now understanding various operational states of the PNP configuration with main load current flowing through the N-type regions, one of ordinary skill could derive equivalent arrangements for PNP arrangement with main load current flowing through the P-type regions, and for NPN arrangements.

Referring simultaneously to FIGS. 3D and 3E. The example DSDB-BJT 200 is shown as monolithic structure. That is, the upper base 202 and upper collector-emitter 206 are associated with or proximate to an upper portion of the drift region 304. Similarly, the lower base 204 and lower collector-emitter 208 are associated with or proximate to a lower portion of the drift region 304. The example drift region 304 is a continuous structure. The example DSDB-BJT 200 may be manufactured by creating the upper base 202 and upper collector-emitter 206 on an upper side of a wafer. The wafer is then flipped and bonded to a handle wafer, and thereafter the lower base 204 and lower collector-emitter 208 are created on the second side of the wafer. Having a continuous drift region 304 may mean that, for positive polarity on the upper terminal 102, charge carrier injection into the upper base 202 (e.g., FIG. 3D) drops the V_{ceon} sufficiently that charge carrier injection from both sides (e.g., FIG. 3E) provides a small additional benefit. Stated otherwise, for devices in which the drift region 304 is continuous, charge carrier injection into the emitter-base (e.g., FIG. 3D) in many cases provides sufficient V_{ceon} reduction, and the further incremental reduction in forward voltage drop attributable to injecting charge carriers in the collector-base (e.g., FIG. 3E) may not justify the additional components and part counts.

Referring again to FIG. 3A. In the passive-off arrangement of FIG. 3A, and with applied voltage as shown, a depletion region forms within the drift region 304. The amount of voltage/current blocking provided by the DSDB-BJT 200 is directly related to the thickness T of the drift region 304. For example, for the drift region 304 of thickness about 150 to 160 microns, the DSDB-BJT 200 may block about 1200V. Thus, monolithic DSDB-BJTs 200 of FIG. 3A may be constructed on wafers initially thicker than 160 microns. Once the first side is complete and the wafer is flipped for construction of the second side, the wafers may be thinned to about 150 to 160 microns prior to creation of the second-side base and collector-emitter regions.

However, DSDB-BJTs may be created with non-continuous drift regions. For example, DSDB-BJTs may manufactured by creating a plurality of partial components, such as each partial component comprising a base region, a collector-emitter region, and a drift region. The partial components may be diced or singulated, and then a DSDB-BJT may be created by bonding the drift regions of two partial components.

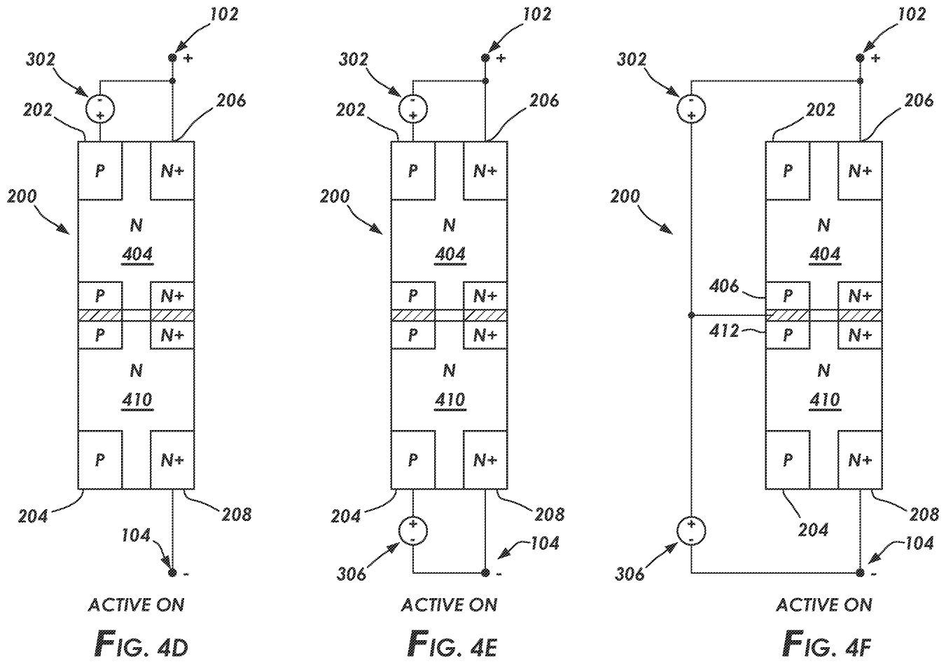

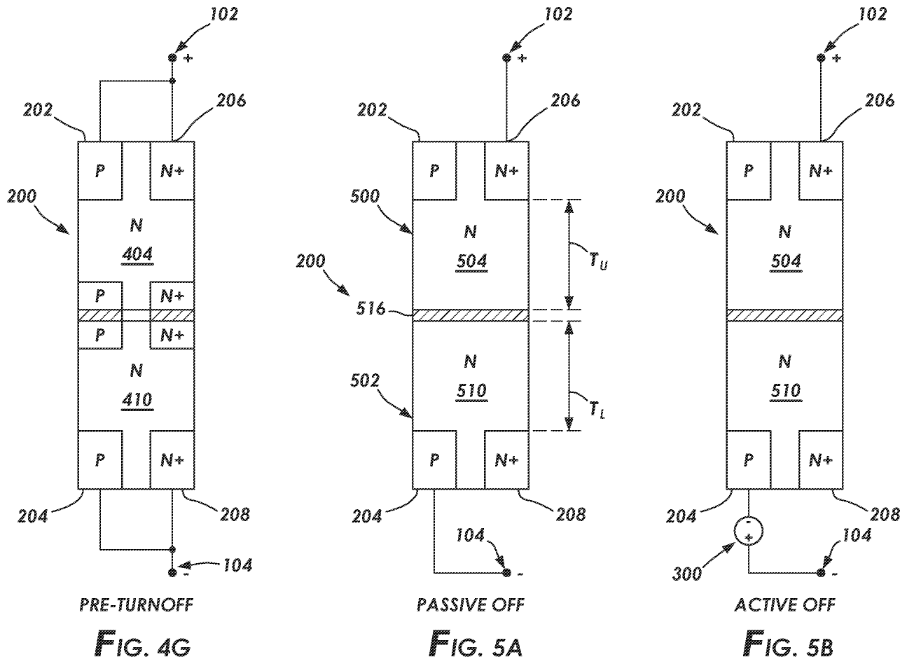

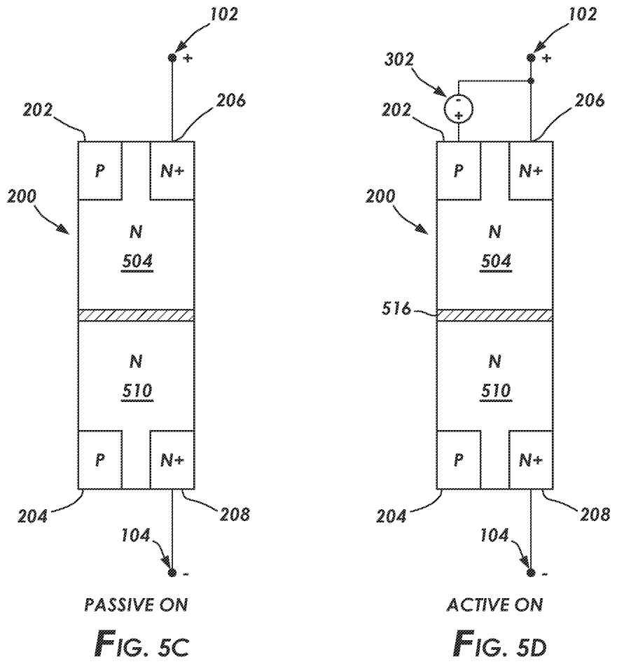

FIGS. 4A-4G show, in shorthand form, a partial cross-sectional view of an example DSDB-BJT of modular construction. Referring initially to FIG. 4A, the example DSDB-BJT 200 of FIG. 4A comprises an upper component 400 and a lower component 402. The upper component 400 defines the upper base 202, the upper collector-emitter 206, and an upper drift region 404. The upper component 400 further defines an internal P-type region 406 and internal N-type region 408. The example DSDB-BJT 200 further comprises the lower component 402. The lower component 402 defines the lower base 204, the lower collector-emitter 208, and a lower drift region 410. The lower component 402 further defines an internal P-type region 412 and internal N-type region 414.

The upper component 400 and the lower component 402 may be constructed on the same wafer or different wafers. After singulation of the upper component 400 and the lower component 402, the DSDB-BJT 200 of FIG. 4A may be assembled by bonding the “backsides” of the upper component 400 to the lower component 402. Stated otherwise, the DSDB-BJT 200 of FIG. 4A may be assembled by bonding the drift regions 404 and 410 of the upper component 400 and lower component 402, respectively. The bonding may involve use of a metallic material (e.g., solder, aluminum) to electrically and mechanically couple the upper drift region 404 to the lower drift region 410. In the example of FIG. 4A, metallic material 416 bonds the P-type region 406 and 412, and metallic material 418 bonds the N-type regions 408 and 414.

FIGS. 4A-4G show seven example states of the DSDB-BJT 200 of modular construction, and arranged for the main load current to be carried across or through the N-type regions, the seven states being: passive off (FIG. 4A); active off (FIG. 4B); passive on (FIG. 4C); active on (FIG. 4D); a first alternative active on (FIG. 4E); a second alternative active on (FIG. 4F); and pre-turn off (FIG. 4G). In the examples of FIGS. 4A-4G, the switch assembly 100 is again assumed to be forward biased (i.e., having the more positive polarity associated with the upper terminal 102 relative to the lower terminal 104).

FIG. 4A shows a passive-off arrangement of the example DSDB-BJT 200 of modular construction. The upper base 202 is electrically floated by the driver 108. The upper collector-emitter 206 is coupled to the upper terminal 102, such as through the upper cascode FET 220 or its body diode 228. The lower base 204 is coupled to the lower terminal 104 by the driver 108. The lower collector-emitter 208 is electrically floated, such as by the lower cascode FET 210 being open and its body diode 218 being non-conductive because of the applied voltage. In the arrangement of FIG. 4A, no appreciable current flows through the DSDB-BJT 200 because of the blocking performed by PN junction formed between the lower base 204 and the lower drift region 410. Again, the state of FIG. 4A is referred as “passive off” because the electrical arrangement can be implemented with purely passive components. As before, in the passive-off arrangement the DSDB-BJT 200 blocks voltage and current, and thus the non-conductive lower cascode FET 210 may experience a relatively small drain-to-source voltage (e.g., 30V or less for 1200V applied across the upper terminal 102 and lower terminal 104).

FIG. 4B shows an active-off arrangement of the example DSDB-BJT 200 of modular construction. In particular, the upper base 202 is electrically floated by the driver 108. The upper collector-emitter 206 is coupled to the upper terminal 102, such as through the upper cascode FET 220 or its body diode 228. The lower base 204 is coupled, through the driver 108, to the lower terminal 104 by way of a voltage source 300. The lower collector-emitter 208 is electrically floated, such as by the lower cascode FET 210 being open and its body diode 218 being non-conductive because of the applied voltage. The voltage source 300 provides a negative bias to the lower base 204 relative to the lower collector-emitter 208. Thus again, in the active-off arrangement no appreciable current flows through the DSDB-BJT 200 because of the blocking performed by the PN junction formed between the lower base 204 and the lower drift region 410.

FIG. 4C shows a passive-on arrangement of the example DSDB-BJT 200 of modular construction. In particular, the upper base 202 is electrically floated by the driver 108. The upper collector-emitter 206 is coupled to the upper terminal 102, such as through the upper cascode FET 220 or its body diode 228. The lower base 204 is electrically floated by the driver 108. The lower collector-emitter 208 is coupled to the lower terminal 104 by way of the lower cascode FET 210. The example state of FIG. 4C is referred as “passive on” because the conductive state does not involve injection of charge carriers to lower the forward voltage drop V_{CEON}. An example of injection of charge carriers is shown in the active-on arrangement of FIG. 4D.

FIG. 4D shows an active-on arrangement of the example DSDB-BJT 200 of modular construction, and still with the switch assembly 100 forward biased. In particular, the upper base 202 is coupled, through the driver 108, to the upper terminal 102 by way of a voltage source 302. The upper collector-emitter 206 is coupled to the upper terminal 102, such as through the upper cascode FET 220 or its body diode 228. The lower base 204 is electrically floated by the driver 108. The lower collector-emitter 208 is coupled to the lower terminal 104 through lower cascode FET 210. The voltage source 302 provides a positive bias to the upper base 202 relative to the upper collector-emitter 206, and the voltage source 302 may provide any suitable bias voltage (e.g., 0.2 V to 2V). The voltage source 302 injects charge carriers across the PN junction into the upper drift region 404, which lowers forward voltage drop V_{CEON}, measured from the upper collector-emitter 206 to the lower collector-emitter 208, to about 0.2V for 30A of main current flow.

FIG. 4E shows a first alternative active-on arrangement of the example DSDB-BJT 200 of modular construction, still with the switch assembly 100 forward biased. In particular, the upper base 202 is coupled, through the driver 108, to the upper terminal 102 by way of the voltage source 302. The upper collector-emitter 206 is coupled to the upper terminal 102, such as through the upper cascode FET 220 or its body diode 228. The lower base 204 is coupled, through the driver 108, to the lower terminal 104 by way of a voltage source 306. The lower collector-emitter 208 is coupled to the lower terminal 104 through lower cascode FET 210. The voltage source 302 provides a positive bias to the upper base 202 relative to the upper collector-emitter 206, and the voltage source 306 provides a positive bias to the lower base 204 relative to the lower collector-emitter 208. The voltage source 302 injects charge carriers across the upper PN junction into the upper drift region 404, and the voltage source 306 injects charge carriers across the lower PN junction in the lower drift region 410. The injection of charge carriers lowers forward voltage drop V_{CEON} measured from the upper collector-emitter 206 to the lower collector-emitter 208.

FIG. 4F shows a second alternative active-on arrangement of the example DSDB-BJT 200 of modular construction, still with the switch assembly 100 forward biased. In particular, the internal P-type region 406 is coupled, through the driver 108, to the upper terminal 102 by way of the voltage source 302. The upper collector-emitter 206 is coupled to the upper terminal 102, such as through the upper cascode FET 220 or its body diode 228. The internal P-type region 412 is coupled, through the driver 108, to the lower terminal 104 by way of the voltage source 306. The lower collector-emitter 208 is coupled to the lower terminal 104 through lower cascode FET 210. The voltage source 302 injects charge carriers across the PN junction into the upper drift region 404, and the voltage source 306 injects charge carriers across the PN junction in the lower drift region 410. The injection of charge carriers lowers forward voltage drop V_{CEON} measured from the upper collector-emitter 206 to the lower collector-emitter 208.

FIG. 4G shows a pre-turnoff arrangement of the example DSDB-BJT 200 of modular construction. In particular, the upper base 202 is coupled, by way of the driver 108, to the upper terminal 102. The upper collector-emitter 206 is coupled to the upper terminal 102, such as through the upper cascode FET 220 or its body diode 228. The lower base 204 is coupled, by the driver 108, to the lower terminal 104. The lower collector-emitter 208 is coupled to the lower terminal 104 by way of the lower cascode FET 210. An equivalent arrangement may be to omit the coupling of the upper base 202 to the upper terminal 102.

Here again, with respect to transitions of the switch assembly 100 from non-conductive to conductive, the example DSDB-BJT 200 may be arranged to transition from either the passive-off arrangement of FIG. 4A or active-off arrangement of FIG. 4B directly to one of the active-on arrangements of FIG. 4D, 4E, or 4F without implementing an intermediate arrangement or state. Nevertheless, the passive-on arrangement of FIG. 4C may find use in some circumstances. With the respect to transitions of the switch assembly 100 from conductive to non-conductive, the example DSDB-BJT 200 may be transitioned from one of the active-on arrangements of FIG. 4D, 4E, or 4F directly to the active-off arrangement of FIG. 4B or the passive-off arrangement of FIG. 4A without implementing an intermediate arrangement or state. Nevertheless, the passive-on arrangement of FIG. 4C and the pre-turnoff arrangement of FIG. 4G may find use in some circumstances.

The examples of FIGS. 4A-4G are for the switch assembly 100 being forward biased. However, the example DSDB-BJT 200 of modular construction is a symmetrical device, and now understanding how to control current through the DSDB-BJT when the switch assembly 100 is forward biased, control of current when the switch assembly 100 is reverse biased (i.e., having the more positive polarity associated with the lower terminal 104 relative to the upper terminal 102) directly follows.

The example DSDB-BJT 200 of modular construction shown in FIGS. 4A-4G may be manufactured by creating the bases and collector-emitters, then flipping the wafer and bonding the wafer to a handle wafer, and thereafter the internal P-type regions and N-type regions are created (or vice versa). Once singulated, an upper component (e.g., 400) is bonded to a lower component (e.g., 402) to create the overall DSDB-BJT 200.

Having the upper drift region 404 coupled to the lower drift region 410 through internal P-and N-type regions may mean that charge carrier injection into either the upper drift region 404 or the lower drift region 410 drops the V_{ceon} sufficiently that charge carrier injection from both sides (e.g., FIGS. 4E or 4F) provides only incremental additional benefit. Stated otherwise, for devices in which the drift regions 404 and 410 are coupled through PN junctions such as shown in FIGS. 4A-4G, charge carrier injection into the emitter-base (e.g., FIG. 4D) in many cases provides sufficient V_{ceon} reduction, and the incremental reduction in forward voltage drop attributable to additionally injecting charge carriers in the collector-base (e.g., FIG. 4E) or into the lower drift region 410 through the internal P-type region 412 (FIG. 4F) may not justify the additional components and part counts.

Referring simultaneously to FIGS. 4A and 4B. In the passive-or active-off arrangements of FIGS. 4A and 4B, and with applied voltage as shown, a depletion region forms within the drift region 410 extending from the lower base 204. However, because of the internal P-and N-type regions, the depletion region formed in association with the lower base 204 may “cross” the bonding into the upper drift region 404. It follows, the amount of voltage/current blocking provided by the DSDB-BJT 200 of modular constructions is directly related to the combined thickness (e.g., T_{U}+T_{L}) of the drift regions 404 and 410. For example, for a combined of thickness about 150 to 160microns, the DSDB-BJT 200 of modular construction may block about 1200V.

The example monolithic DSDB-BJT 200 of FIGS. 3A-3F, and the example modular DSDB-BJT 200 of FIGS. 4A-4G, may initially be constructed on a thick wafer (e.g., 500 microns), and then the thick wafer may be thinned. In the case of the monolithic DSDB-BJT 200, the wafer may be thinned to about 150 to 160 microns prior to creation of the lower base and lower collector-emitter. For the components 400 and 402 of the modular DSDB-BJT 200 shown in FIGS. 4A-4G, the wafer may be thinned to about 75to 80 microns prior to creating the “internal” PN junctions, and then singulated.

The amount a wafer can be thinned, such as by backside grind, is dependent upon the diameter of the wafer. Smaller diameter wafers may be thinned more than larger diameter wafers. For example, a six-inch diameter wafer, which may have an initial thickness of about 500 microns, may be thinned to about 75 or 80 microns without significant warpage. However, larger diameter wafers, such as eight- or twelve-inch diameter wafers, are thicker (e.g., 750 microns) to provide structural stability for the wafer itself. Thinning a larger diameter wafer is not practical in most situations, as the larger diameter wafers tend to warp significantly when thinned. Stated otherwise, the monolithic DSDB-BJT 200 of FIG. 3A-3F, and the upper/lower components of the modular DSDB-BJT 200 of FIGS. 4A-4G, may be constructed on six-inch wafers; however, construction of the either the monolithic or modular version may not be practical on larger diameter wafers (e.g., eight inch, twelve inch) because of limitations on thinning caused by warpage. The specification now turns to another modular DSDB-BJT 200 that may nevertheless be constructed on the larger diameter wafers.

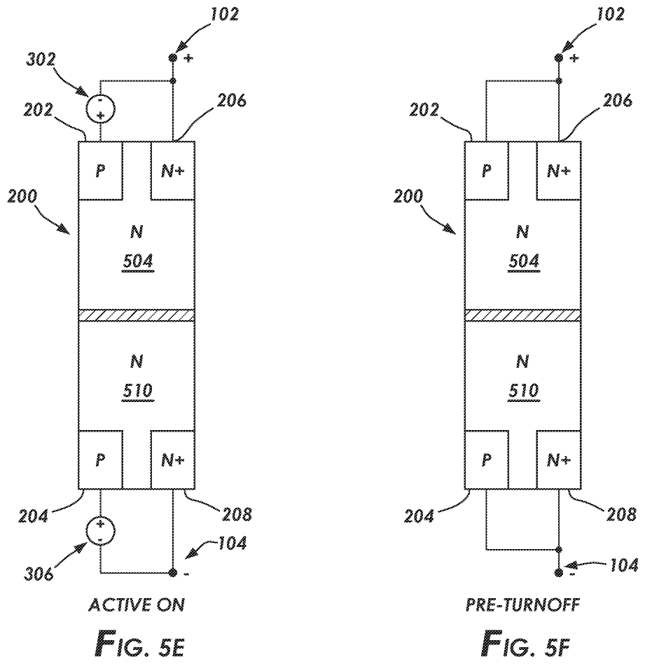

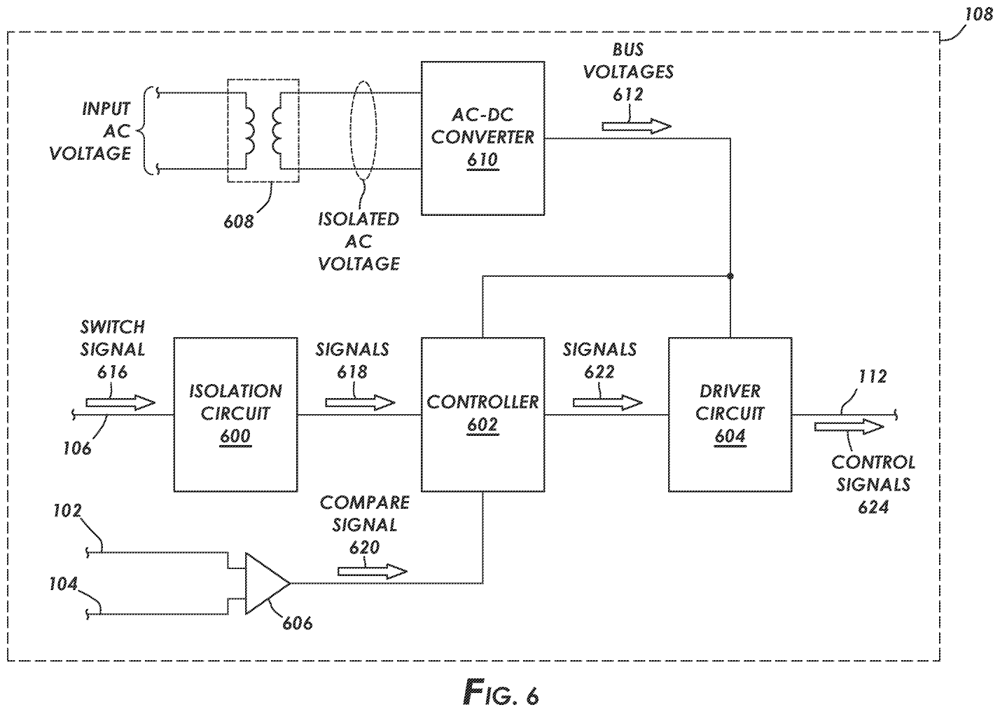

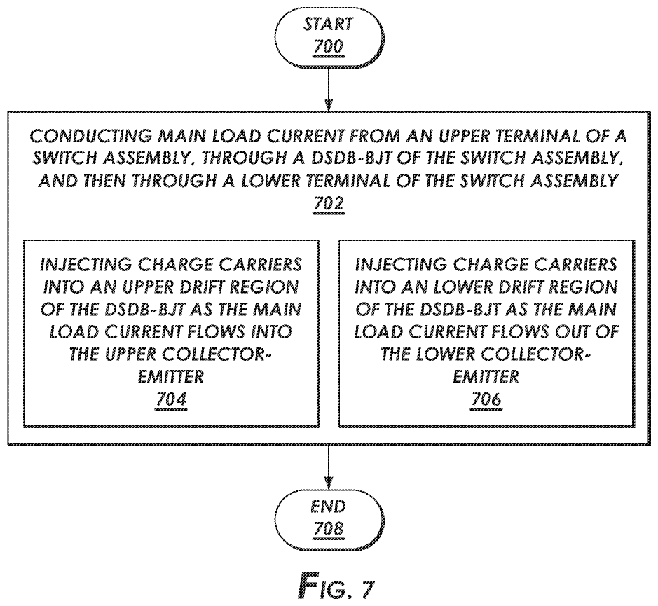

FIGS. 5A-5F show, in shorthand form, a partial cross-sectional view of an example DSDB-BJT of modular construction. Referring initially to FIG. 5A, the example DSDB-BJT 200 of FIG. 5A comprises an upper component 500 and a lower component 502. The upper component 500 defines the upper base 202, the upper collector-emitter 206, and an upper drift region 504. The example upper component 500 omits the internal P-type and N-type regions of the embodiments of FIG. 4A-4G. The example DSDB-BJT 200 further comprises the lower component 502. The lower component 502 defines the lower base 204, the lower collector-emitter 208, and a lower drift region 510. The lower component 502 omits the internal P-type and N-type regions of the embodiments of FIG. 4A-4G.

The upper component 500 and the lower component 502 may be constructed on the same wafer or different wafers. After singulation of the upper component 500 and the lower component 502, the DSDB-BJT 200 of FIG. 5A may be assembled by bonding the “backsides” of the upper component 500 to the lower component 502. Stated otherwise, the DSDB-BJT 200 of FIG. 5A may be created by bonding the drift regions 504 and 510 of the upper component 500 and lower component 502, respectively. The bonding may involve use of a metallic material (e.g., solder, aluminum) to electrically and mechanically couple the upper drift region 504 to the lower drift region 510. In the example of FIG. 5A, the metallic material 516 bonds the N-type drift regions 504 and 510. Stated otherwise, the metallic material 516 mechanically and electrically couples the N-type drift regions 504 and 510. In order to reduce or avoid creation of a Schottky barrier at the metal/silicon interface, in some examples slight N-type doping may be present on the “backsides” of each component 500 and 502 adjacent to the metallic material 516, though the doping to reduce or avoid the Schottky barriers is not expressly shown.

Still referring to FIG. 5A. In the passive-off arrangement of FIG. 5A, and with applied voltage as shown, a depletion region forms within the lower drift region 510 extending from the lower base 204. However, the depletion region formed in association with the lower base 204 may not “cross” the bonding into the upper drift region 504. That is to say, the metallic material 516 can be thought of as an infinite supply of electrons, and thus the depletion region formed starting at the lower base 204 cannot extend through the metallic material into the upper drift region 504 because of the absence of the internal P-type regions. It follows, the amount of voltage/current blocking provided by the DSDB- BJT 200 of modular constructions is directly related to the individual thickness T of each of the drift regions 504 and 510. For example, for a thickness TL of the lower drift region 510 of about 150 to 160 microns, the DSDB-BJT 200 of modular construction may block about 1200V. Similarly, but for opposite applied polarity, for a thickness T_{U} of the upper drift region 504 of about 150 to 160 microns, the DSDB-BJT 200 of modular construction may block about 1200V. In most cases, the thicknesses T_{U} and T_{L} will be about the same; however, there may be instances where a DSDB-BJT 200 may benefit from having different voltage/current blocking ability depending upon the externally applied voltage.

FIGS. 5A-5F show six example states of the example DSDB-BJT 200 of modular construction, and arranged for the main load current to be carried across or through the N-type regions, the six states being: passive off (FIG. 5A); active off (FIG. 5B); passive on (FIG. 5C); an alternate active on (FIG. 5D); active on (FIG. 5E); and pre-turn off (FIG. 5F). In the examples of FIGS. 5A-5F, the switch assembly 100 is again assumed to be forward biased (i.e., having the more positive polarity associated with the upper terminal 102 relative to the lower terminal 104).

FIG. 5A shows a passive-off arrangement of the example DSDB-BJT 200 of modular construction. The upper base 202 is electrically floated by the driver 108. The upper collector-emitter 206 is coupled to the upper terminal 102, such as through the upper cascode FET 220 or its body diode 228. The lower base 204 is coupled to the lower terminal 104 by the driver 108. The lower collector-emitter 208 is electrically floated, such as by the lower cascode FET 210 being open and its body diode 218 being non-conductive because of the applied voltage. In the arrangement of FIG. 5A, no appreciable current flows through the DSDB-BJT 200 because of the blocking performed by PN junction formed between the lower base 204 and the lower drift region 510. Again, the state of FIG. 5A is referred as “passive off” because the electrical arrangement can be implemented with purely passive components. As before, in the passive-off arrangement the DSDB-BJT 200 blocks voltage and current, and thus the non-conductive lower cascode FET 210 may experience a relatively small drain-to-source voltage (e.g., 30V or less for 1200V applied across the upper terminal 102 and lower terminal 104).

FIG. 5B shows an active-off arrangement of the example DSDB-BJT 200 of modular construction. In particular, the upper base 202 is electrically floated by the driver 108. The upper collector-emitter 206 is coupled to the upper terminal 102, such as through the upper cascode FET 220 or its body diode 228. The lower base 204 is coupled, through the driver 108, to the lower terminal 104 by way of a voltage source 300. The lower collector-emitter 208 is electrically floated, such as by the lower cascode FET 210 being open and its body diode 218 being non-conductive because of the applied voltage. The voltage source 300 provides a negative bias to the lower base 204 relative to the lower collector-emitter 208. Thus again, in the active-off arrangement no appreciable current flows through the DSDB-BJT 200 because of the blocking performed by the PN junction formed between the lower base 204 and the lower drift region 510.

FIG. 5C shows a passive-on arrangement of the example DSDB-BJT 200 of modular construction. In particular, the upper base 202 is electrically floated by the driver 108. The upper collector-emitter 206 is coupled to the upper terminal 102, such as through the upper cascode FET 220 or its body diode 228. The lower base 204 is electrically floated by the driver 108. The lower collector-emitter 208 is coupled to the lower terminal 104 by way of the lower cascode FET 210. The example state of FIG. 5C is referred as “passive on” because the conductive state does not involve injection of charge carriers to lower the forward voltage drop V_{CEON}. The voltage drop across the DSDB-BJT 200 in the arrangement of FIG. 5C is based on the substrate resistance of each drift region. Thus, for example, for an upper drift region 504 being about 160 microns thick, the upper drift region 504 may present about two Ohms of resistance, and for the lower drift region 510 being about 160 microns thick, the lower drift region 510 may present about two Ohms of resistance, for a total resistance across the DSDB-BJT 200 of about 4 Ohms. Thus, for the example 30A of main load current, in the passive-on arrangement of FIG. 5C the DSDB-BJT 200 presents about a 120V drop measured from the upper collector-emitter 206 to the lower collector-emitter 208.

FIG. 5D shows an active-on arrangement of the example DSDB-BJT 200 of modular construction, and still with the switch assembly 100 forward biased. In particular, the upper base 202 is coupled, through the driver 108, to the upper terminal 102 by way of a voltage source 302. The upper collector-emitter 206 is coupled to the upper terminal 102, such as through the upper cascode FET 220 or its body diode 228. The lower base 204 is electrically floated by the driver 108. The lower collector-emitter 208 is coupled to the lower terminal 104 through lower cascode FET 210. The voltage source 302 provides a positive bias to the upper base 202 relative to the upper collector-emitter 206, and the voltage source 302 may provide any suitable bias voltage (e.g., 0.2V to 2V). The voltage source 302 injects charge carriers across the PN junction into the upper drift region 504, which lowers forward voltage drop across the upper drift region, but does not lower the forward voltage drop across the lower drift region 510 because the charge carriers created at the PN junction cannot cross the metallic material 516. For the example 30A of main load current, the voltage drop across the upper drift region 504 may be reduced to about 0.2V; however, within no charge carrier injection into the lower drift region 510, the total V_{CEON} from the collector-emitter 206 to the collector-emitter 208 may be about of 60.2V (e.g., 0.2V across the upper drift region 504, and 60V across the lower drift region 510 given the 2 Ohm resistance of the lower drift region 510).

FIG. 5E shows an active-on arrangement of the example DSDB-BJT 200 of modular construction, still with the switch assembly 100 forward biased. In particular, the upper base 202 is coupled, through the driver 108, to the upper terminal 102 by way of the voltage source 302. The upper collector-emitter 206 is coupled to the upper terminal 102, such as through the upper cascode FET 220 or its body diode 228. The lower base 204 is coupled, through the driver 108, to the lower terminal 104 by way of a voltage source 306. The lower collector-emitter 208 is coupled to the lower terminal 104 through lower cascode FET 210. The voltage source 302 provides a positive bias to the upper base 202 relative to the upper collector-emitter 206, and the voltage source 306 provides a positive bias to the lower base 204 relative to the lower collector-emitter 208. The voltage source 302 injects charge carriers across the upper PN junction into the upper drift region 504, and the voltage source 306 injects charge carriers across the lower PN junction in the lower drift region 510. The injection of charge carriers lowers forward voltage drop V_{CEON} across the entire DSDB-BJT 200 to about 0.4V for an example 30A of main load current.

FIG. 5F shows a pre-turnoff arrangement of the example DSDB-BJT 200 of modular construction. In particular, the upper base 202 is coupled, by way of the driver 108, to the upper terminal 102. The upper collector-emitter 206 is coupled to the upper terminal 102, such as through the upper cascode FET 220 or its body diode 228. The lower base 204 is coupled, by the driver 108, to the lower terminal 104. The lower collector-emitter 208 is coupled to the lower terminal 104 by way of the lower cascode FET 210. An equivalent arrangement may be to omit the coupling of the upper base 202 to the upper terminal 102.

Here again, with respect to transitions of the switch assembly 100 from non-conductive to conductive, the example DSDB-BJT 200 may be arranged to transition from either the passive-off arrangement of FIG. 5A or active-off arrangement of FIG. 5B directly to one of the active-on arrangements of FIG. 5D or 5E without implementing an intermediate arrangement or state. Nevertheless, the passive-on arrangement of FIG. 5C may find use in some circumstances. With the respect to transitions of the switch assembly 100 from conductive to non-conductive, the example DSDB-BJT 200 may be transitioned from the active-on arrangements of FIG. 5E directly to the active-off arrangement of FIG. 5B or the passive-off arrangement of FIG. 5A without implementing an intermediate arrangement or state.

Here again, the examples of FIGS. 5A-5F are for the switch assembly 100 being forward biased. However, the example DSDB-BJT 200 of modular construction is a symmetrical device, and now understanding how to control current through the DSDB-BJT when the switch assembly 100 is forward biased, control of current when the switch assembly 100 is reverse biased (i.e., having the more positive polarity associated with the lower terminal 104 relative to the upper terminal 102) directly follows.

The example DSDB-BJT 200 of modular construction shown in FIGS. 5A-5F may be manufactured by creating the components 500 and 502 on a substrate. The components 500 and 502 may then be singulated. A first modular component (e.g., upper component 500) is bonded to a second modular component (e.g., lower component 502) to create the overall DSDB-BJT 200. The example modular components may initially be constructed on a thick wafer (e.g., 500 microns), and then the thick wafer may be thinned to about 150 to 160 microns prior to singulation. It follows that the modular components of FIGS. 5A-5F may be constructed on any diameter of wafer, as the wafer prior to bonding is still relatively thick (e.g., 150 to 160 microns), and thus warpages is not a major concern.

In the various examples in which the charge carriers are injected from both sides of the DSDB-BJT 200, such as the active-on arrangements of FIGS. 3E, 4E, 4F, and 5E, the injection of charge carriers may take many forms. The examples of FIGS. 3E, 4E, 4F, and 5E use voltage sources. In the case of voltage sources, the magnitudes of the voltages may be the same. For example, the magnitude of the voltage of the voltage source 302 may be the same as the magnitude of the voltage of the voltage source 306. In other cases, the voltages may be different. For example, magnitude of the voltage on the collector-side (e.g., voltage source 302) may be greater than the voltage on the emitter side (e.g., voltage source 306).

Considered from the standpoint of the magnitude of control current supplied, in some cases the magnitude of control current supplied to the upper component 400/500 may be the same as the magnitude of control current supplied to the lower component 402/502. In other cases, the magnitude of control current supplied to the upper components 400/500 may be different than the magnitude of control current supplied to the lower components 402/502. The difference in magnitude may be intentional, such as voltage sources 302 and 306 having different setpoint voltages, or the difference in magnitude may be un-intentionally, such as slight differences in control current caused by manufacturing variability for the same applied voltage. In still other cases, the sources 300 and 302 may be set up as controlled current sources, supplying variable voltages to achieve respective setpoint currents, and the setpoints may be the same or different.

FIG. 6 shows a block diagram of an example driver 108. In particular, the example driver 108 includes an isolation circuit 600, a controller 602, a driver circuit 604, a comparator 606, a transformer 608, and an AC-DC converter 610. A primary winding of transformer 608 is coupled to an input AC voltage. Transformer 608 is configured to generate isolated AC voltage on its secondary winding based on the input AC voltage. In some embodiments, transformer 608 may include a core made of ferrous material and/or one or more taps on the secondary winding. Although a single transformer is depicted in FIG. 6, in other examples multiple transformers may be employed to provide different AC voltages to AC-DC converter 610.

The AC-DC converter 610 is configured to generate bus voltages 612. In some examples, the bus voltages 612 may include multiple voltage levels (e.g., 3.3V, 5V, 12V,) for use by controller 602 to generate the voltages for various ones of control signals 622 applied driver circuit 604. Similarly, the bus voltages may be used by the driver circuit 604 to generate the voltages for various ones of control signals 624 applied to the bidirectional switch 110 by way of the connections 112. The AC-DC converter 610 may be implemented using a rectifier circuit, one or more capacitors, one or more power converter circuits (e.g., buck converters), or any other suitable circuit components or sub-circuits.

The driver 108 may be in a different electrical domain than circuits that generate the switch signal 616 applied to the control terminal 106. To account for the difference in electrical domains, isolation circuit 600 is employed. The isolation circuit 600 is configured to generate signals 618 based on switch signal 616, such that signals 618 are in a different electrical domain from switch signal 616. Isolation circuit 600 may be implemented using optocouplers, capacitive isolation devices, or any other circuits configured to translate a signal from one electrical domain to another.

Comparator 606 has a first input coupled to the upper terminal 102, a second input coupled to the lower terminal 104, and defines a compare output. The comparator 606 is configured to generate compare signal 620 on the compare output based on respective voltage levels of terminals 102 and 104. A voltage level of compare signal 620 may indicate which of terminals 102 or 104 has a greater voltage, and thus indicate whether the switch assembly 100 is forward biased or reverse biased. For example, an asserted state of the compare signal 620 may indicate forward bias, while a non-asserted state of the compare signal 620 may indicate reverse bias. Comparator 606 may be implemented using a differential amplifier circuit, a Schmitt trigger circuit, or any other suitable circuit configured to generate an output signal whose voltage level is based on a comparison of respective voltage levels of at least two input signals.

Controller 602 is configured to generate signals 622 applied to the driver circuit 604. Responsive to the signals 622, the driver circuit 604 arranges the bidirectional switch 110 into various states as described in FIGS. 3A-3F, 4A-4G, and 5A-5F. Controller 602 may be implemented using individual circuit components, an application specific integrated circuit (ASIC), a microcontroller configured to execute software or program instructions, a reduced instruction set computer (RISC), a digital signal processor (DSP) circuit, a processor or processor core configured to execute software or program instructions, a programmable-logic device (PLD), a field programmable gate array (FPGA), a programmable system-on-a-chip (SoC), or any suitable combination thereof.

Driver circuit 604 is configured to generate control signals 624 using signals 622 and one or more of the voltage levels included in bus voltages 612. The driver circuit 604 may be used to place the upper cascode FET 220, the DSDB-BJT 200, and the lower cascode FET 210 into the various states as described in FIGS. 3A-3F, 4A-4G, and 5A-5F. In various embodiments, driver circuit 604 may be implemented using multiple switches, FETs, or any other suitable switching devices.

FIG. 7 shows method in accordance with at least some embodiments. In particular, the method starts (block 700) and comprises conducting main load current from an upper terminal of a switch assembly, through a DSDB-BJT of the switch assembly, and then through a lower terminal of the switch assembly (block 702). The conducting may be by: injecting charge carriers into an upper drift region of the DSDB-BJT as the main load current flows into the upper collector-emitter (block 704); and simultaneously injecting charge carriers into a lower drift region of the DSDB-BJT as main load current flows out of the lower collector-emitter (block 706). Thereafter, the method ends (block 708), likely to be restarted in the next cycle of the voltage applied to switch assembly 100.

Many of the electrical connections in the drawings are shown as direct couplings having no intervening devices, but not expressly stated as such in the description above. Nevertheless, this paragraph shall serve as antecedent basis in the claims for referencing any electrical connection as “directly coupled” for electrical connections shown in the drawing with no intervening device(s). Moreover, this paragraph shall not negate that a base electrically connected to a collector-emitter through a transistor may be referred to as “directly coupled.”

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

1. A method comprising:
conducting main load current from an upper terminal of a switch assembly, through
a bipolar junction device of the switch assembly, and then through a lower terminal of the switch assembly, the conducting by:
injecting charge carriers into an upper drift region of the bipolar junction device as the main load current flows into an upper collector-emitter of the bipolar junction device; and simultaneously
injecting charge carriers into a lower drift region of the bipolar junction device as main load current flows out of a lower collector-emitter of the bipolar junction device.

2. The method of claim 1 wherein:
injecting charge carriers into the upper drift region of the bipolar junction device comprises injecting an upper control current into an upper base of the bipolar junction device; and
injecting charge carriers into the lower drift region of the bipolar junction device comprises injecting a lower control current into a lower base of the bipolar junction device.

3. The method of claim 2 wherein a magnitude of the upper control current is equal to a magnitude of the lower control current.

4. The method of claim 2 wherein a magnitude of an upper bias voltage between the upper base and upper collector-emitter is different a magnitude of a lower bias voltage between the lower base and the lower collector-emitter.

5. The method of claim 2 wherein a magnitude of the upper control current different than a magnitude of the lower control current.

6. The method of claim 2 wherein conducting the main load current comprises conducting the main load current through the bipolar junction device that is a monolithic structure with a continuous drift region.

7. The method of claim 2 wherein conducting the main load current comprises conducting main load current through the upper collector-emitter, then through the upper drift region, then though a metallic material that bonds to the upper drift region to the lower drift region, and then through the lower collector-emitter.

8. The method of claim 1 wherein:
injecting charge carriers into the upper drift region of the bipolar junction device comprises injecting an upper control current through a metallic material that bonds the upper drift region to the lower drift region; and
injecting charge carriers into the lower drift region of the bipolar junction device comprises injecting a lower control current through the metallic material.

9. A switch assembly comprising:
an upper terminal, a lower terminal, and a control input;
a double-sided double-base bipolar junction transistor (DSDB-BJT) defining an upper base, an upper collector-emitter, a lower base, and a lower collector-emitter;
an upper-main FET defining a first lead coupled to the upper terminal, a second lead coupled to the upper collector-emitter, and a gate;
a lower-main FET defining a first lead coupled to the lower collector-emitter, a second lead coupled to the lower terminal, and a gate;
a driver coupled to the control input, the gate of the upper-main FET, the gate of the lower-main FET, and the upper and lower bases of the DSDB-BJT;
responsive to assertion of the control input, and for a first applied voltage across the upper terminal and lower terminal, the driver configured to:
arrange the DSDB-BJT for conduction;
inject charge carriers into an upper drift region of the DSDB-BJT and simultaneously inject charge carriers into a lower drift region of the DSDB-BJT; and
assert the gate of the lower-main FET to make the lower-main FET conductive such that a first load current flows from the upper terminal to the lower terminal.

10. The switch assembly of claim 9 wherein the DSDB-BJT comprises the upper drift region associated with the upper collector-emitter and the lower drift region associated with the lower collector-emitter, and wherein the upper drift region is bonded to the lower drift region.

11. The switch assembly of claim 10:
wherein when driver injects charge carriers into the upper drift region, the driver is configured to inject an upper current into the upper base; and
wherein when driver injects charge carriers into the lower drift region, the driver is configured to inject a lower current into the lower base.

12. The switch assembly of claim 10:
wherein when the driver injects charge carriers into the upper drift region, the driver is configured to inject an upper control current through a metallic layer that bonds the upper drift region to the lower drift region; and
wherein when the driver injects charge carriers into the lower drift region, the driver is configured to inject a lower control current through the metallic layer.

13. The switch assembly of claim 9 wherein the DSDB-BJT comprises a monolithic structure with a continuous drift region.

14. The switch assembly of claim 13:
wherein when driver injects charge carriers into the upper drift region, the driver is configured to inject an upper current into the upper base; and
wherein when driver injects charge carriers into the lower drift region, the driver is configured to inject a lower current into the lower base.

15. The switch assembly of claim 9 wherein, responsive to de-assertion of the control input, the driver is configured to:
de-assert the gate of the upper-main FET to make the upper-main FET non- conductive;
de-assert the gate of the lower-main FET to make the lower-main FET non- conductive such that no current flows from the lower collector-emitter to the lower terminal; and
arrange the DSDB-BJT into a non-conductive state by coupling the upper base to the upper collector-emitter and coupling the lower base to the lower terminal.

16. The switch assembly of claim 9 wherein, responsive to assertion of the control input, and for a first applied voltage across the upper terminal and the lower terminal, the driver is further configured to assert the gate of the upper-main FET to make the upper-main FET conductive.

17. A switch assembly comprising:
an upper terminal, a lower terminal, and a control input;
a bipolar junction device defining an upper collector-emitter coupled to the upper terminal, a lower base, and a lower collector-emitter;
a lower-main FET defining a first lead coupled to the lower collector-emitter, a second lead coupled to the lower terminal, and a gate;
a driver coupled to the control input, the gate of the lower-main FET, and the lower base of the bipolar junction device;
responsive to assertion of the control input, and for a first applied voltage across the upper terminal and lower terminal, the driver configured to:
arrange the bipolar junction device for conduction, including injection of charge carriers into an upper drift region of the bipolar junction device and simultaneously inject charge carriers into a lower drift region of the bipolar junction device; and
assert the gate of the lower-main FET to make the lower-main FET conductive such that a first load current flows from the upper terminal to the lower terminal.

18. The switch assembly of claim 17 wherein the bipolar junction device comprises the upper drift region associated with the upper collector-emitter and the lower drift region associated with the lower collector-emitter, and wherein the upper drift region is bonded to the lower drift region.

19. The switch assembly of claim 18 wherein when driver injects charge carriers into the lower drift region, the driver is configured to inject a lower current into the lower base.

20. The switch assembly of claim 18 wherein when the driver injects charge carriers into the upper drift region, the driver is configured to inject an upper control current through a metallic layer.

21. The switch assembly of claim 17 wherein the bipolar junction device comprises a monolithic structure with a continuous drift region.

22. The switch assembly of claim 17 wherein, responsive to de-assertion of the control input, the driver is configured to:
de-assert the gate of the lower-main FET to make the lower-main FET non-conductive such that no current flows from the lower collector-emitter to the lower terminal; and
arrange the bipolar junction device into a non-conductive state.
